(19) United States
(12) Patent Application Publication
(10) Pub. No.: US 2012/0160308 A1
(43) Pub. Date: Jun. 28, 2012

(54) PHOTOVOLTAIC CELL MODULE

(75) Inventors: Hsin-Rong Tseng, Tainan City (TW); Chun-Liang Lin, New Taipei City (TW)

(73) Assignee: AU OPTRONICS CORPORATION, Hsinchu (TW)

(21) Appl. No.: 13/069,420

(22) Filed: Mar. 23, 2011

(30) Foreign Application Priority Data
Dec. 24, 2010 (TW) 99145918

(51) Int. Cl. H01L 31/06

(52) U.S. Cl. 136/255

(57) ABSTRACT

A photovoltaic cell module includes a substrate, a first photovoltaic cell and a second photovoltaic cell. The substrate has first and second surfaces. The first photovoltaic cell includes a first electrode layer on the first surface, a first active layer covering the first electrode, and a second electrode covering the first active layer, and the first active layer absorbs the light having a first wavelength range. The second photovoltaic cell is serially connected with the first photovoltaic cell and includes a third electrode layer on the second surface, a second active layer covering the third electrode, and a fourth electrode covering the second active layer, and the second active layer absorbs the light having a second wavelength range. A surface of the second electrode layer of the first photovoltaic cell serves as a light incident surface and a surface of the second photovoltaic cell serves as a light reflective surface.

### CROSS-REFERENCE TO RELATED APPLICATION

This application claims the priority benefit of Taiwan application serial no. 99145918, filed Dec. 24, 2010. The entirety of the above-mentioned patent application is hereby incorporated by reference herein and made a part of this specification.

### TECHNICAL FIELD

The disclosure relates to a photovoltaic cell module, and more particularly to an organic photovoltaic cell (OPV) module.

### BACKGROUND

In recent years, environmental awareness increases. In order to better cope with the shortage of fossil fuels and mitigate the environmental impact incited by fossil fuels, research and development on alternative energy source and renewable energy source are mounting. More particularly, photovoltaic cells, which can directly convert solar energy into electricity, have demonstrated to be a promising potential. Photovoltaic cells can generate electricity directly from sunlight, while hazardous substances, such as carbon dioxide and nitride gases, are not generated during the electricity generation process; hence, environment pollution is greatly reduced.

Generally speaking, in a conventional photovoltaic cell, a first electrode layer, an active layer, and a second electrode layer are sequentially stacked on a substrate. When the photovoltaic cell is irradiated by light, free electron-hole pairs are generated in the active layer by the solar energy, and electrons and holes are caused to move, by the internal electric field formed by the PN junction, respectively toward the two electrodes layers, so as to generate an electric energy storage state. Meanwhile, if a load circuit or an electronic device is connected to the photovoltaic cell, electricity is provided to drive the circuit or the device.

However, the greatest problems encountered by a photovoltaic cell are insufficient light absorption efficiency and insufficient light conversion efficiency. To enhance light absorption efficiency and light conversion efficiency is being actively pursued in the industry.

### SUMMARY

A photovoltaic cell module is introduced herein, wherein the light absorption efficiency of the photovoltaic cell is enhanced to improve the overall efficiency of the photovoltaic cell module.

A photovoltaic cell module introduced herein includes a light incident surface and a light reflective surface. The photovoltaic cell module includes a substrate, a first photovoltaic cell, and a second photovoltaic cell. The substrate includes a first surface and a second surface. The first photovoltaic cell includes a first electrode layer disposed on the first surface of the substrate, a first active layer covering the first electrode layer, and a second electrode layer covering the active layer, wherein the first active layer absorbs the light of a first wavelength range. The second photovoltaic cell is serially connected with the first photovoltaic cell and includes a third electrode layer disposed on the second surface of the substrate, a second active layer covering the third electrode layer, and a fourth electrode layer covering the second active layer, wherein the second active layer absorbs the light of a second wavelength range. Moreover, the surface of the second electrode layer of the first photovoltaic cell serves as a light incident surface, while the surface of the fourth electrode layer of the second photovoltaic cell serves as a light reflective surface.

According to an exemplary embodiment of the photovoltaic cell introduced herein, the first photovoltaic cell and the second photovoltaic cell are respectively disposed at two sides of the substrate to obviate the film layers of the photovoltaic cells from damaging each other during the fabrication process. Moreover, the first active layer absorbs the light of the first wavelength range, while the second active layer absorbs the light of the second wavelength range. This type of design can effectively enhance the light absorption efficiency of the entire wavelength range of the photovoltaic cell module, to improve the overall efficiency of the photovoltaic cell module.

For the sake of clear understanding, several exemplary embodiments accompanied with figures are described in detail below to further describe the disclosure in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a photovoltaic cell module according to one exemplary embodiment of the disclosure.

FIG. 2 is a curve diagram of a light absorption wave band of a photovoltaic cell module according to one exemplary embodiment of the disclosure.

FIGS. 3 and 4A-4B are schematic cross-sectional views of a photovoltaic cell module according to one exemplary embodiment of the disclosure.

FIG. 5 is a schematic cross-sectional view of a photovoltaic cell module according to one exemplary embodiment of the disclosure.

FIG. 6 is a curve diagram of the light absorption efficiency and the light absorption wave band of the photovoltaic cell module in FIG. 5.

FIG. 7 is a curve diagram of the optical film in the photovoltaic cell module in FIG. 5 in which reflectance of the light of a specific wavelength range is generated, while the light of a specific wavelength range is transmitted through.

FIG. 8 is a curve diagram of the light absorption efficiency and wavelength of the photovoltaic cell module in FIG. 5.

### DETAILED DESCRIPTION OF DISCLOSED EMBODIMENTS

FIG. 1 is a schematic cross-sectional view of a photovoltaic cell module according to one exemplary embodiment of the disclosure. Referring to FIG. 1, the photovoltaic cell module 10 of this exemplary embodiment includes a light incident surface 10a and a light reflective surface 10b, and this photovoltaic cell module 10 includes a substrate 100, a first photovoltaic cell A and a second photovoltaic cell B.

The substrate 100 includes a first surface 100a and a second surface 100b. The substrate 100 may be a hard material substrate (such as, a glass substrate, a silicon substrate) or a flexible substrate (such as an organic polymer substrate). The substrate 100 is preferably a flexible substrate. If the substrate 100 is a hard substrate, the photovoltaic cell module 10 may be fabricated using the roll-to-roll process.

The first photovoltaic cell A includes a first electrode layer 110, a first active layer 112, and a second electrode layer 114.

The first electrode layer 110 is disposed on the first surface 100a of the substrate 100. According to an exemplary embodiment of the disclosure, the first electrode layer 110 includes a transparent electrode material. In one exemplary embodiment, the first electrode layer 110 includes a transparent conductive layer 110a and a work function adjustment layer 110b. The transparent conductive layer 110a in this exemplary embodiment includes indium tin oxide, indium zinc oxide, aluminum tin oxide, aluminum zinc oxide, indium germanium zinc oxide or other appropriate metal oxides. The work function adjustment layer 110b serves to provide the first electrode layer 110 to have a more appropriate work function relative to the first active layer 112. The material of the work function adjustment layer 110b includes, for example, cesium carbonate (CsCO₃), zinc oxide (ZnO), or other appropriate work function adjustment materials.

The first active layer 112 covers the first electrode layer 110. The first active layer 1120 absorbs the light of the first wavelength range. According to an exemplary embodiment, the first active layer 112 is constituted with an organic light absorption material and mainly absorbs the light of the visible light band or the light of the infrared light band. If the first active layer 112 absorbs the light of the visible light band, the material of the first active layer 112 may include, for example, (poly(3-hexylthiophene): [6,6]-phenyl-C61-butyric acid methyl ester (P3HT:[60]PCBM)), (poly[2-methoxy-5-(30,70-dimethyloctyloxy)-1,4-phenylenevinylene]: [6,6]-phenyl-C61-butyricacidmethyl ester (MDMO-PPV:[60]PCBM)), or other appropriate materials. If the first active layer 112 absorbs the light of the infrared light band, the material of the first active layer 112 may include, for example, (poly[2,6-(4,4-bis-(2-ethylhexyl)-4H-cyclopenta[2,1-b;3,4-b′] dithiophene)-alt-4,7-(2,1,3-benzothiadiazole)]:[6,6]-phenyl-C71 butyric acid methyl ester (PCPDTBT:[70]PCBM)), (poly[4,8-bis-substituted-benzo[1,2-b:4,5-b′]dithiophene-2,6-diyl-alt-4-substituted-thieno[3,4-b]thio-phene-2,6-diyl]:[6,6]-phenyl-C71 butyric acid methyl ester (PBDTTT:[70]PCBM)), or other appropriate materials.

The second electrode layer 114 covers the first active layer 112. According to an exemplary embodiment, the second electrode layer 114 includes, for example, a transparent electrode material, such as an organic conductive material. Generally speaking, the material of the second electrode layer 114 is selected based on the consideration of its work function and its compatibility with the first active layer 112. Hence, the material of the second electrode layer 114 may include Poly(3,4-ethylenedioxythiophene) poly(styrenesulfonate) (PEDOT:PPS), indium titanium oxide, or other appropriate materials.

The second photovoltaic cell B and the first photovoltaic cell A are electrically connected in series and the second photovoltaic cell B includes a third electrode layer 120, a second active layer 122, and a fourth electrode layer 124.

The third electrode layer 120 is disposed on the second surface 100b of the substrate 100. According to an exemplary embodiment, the third electrode layer 120 includes a transparent electrode material. In one exemplary embodiment, the third electrode layer 120 includes a transparent conductive layer 120a and a work function adjustment layer 120b. In this exemplary embodiment, the material of the transparent conductive layer 120a includes, for example, indium tin oxide, indium zinc oxide, aluminum tin oxide, aluminum zinc oxide, indium germanium zinc oxide, or other appropriate metal oxides. The work function adjustment layer 120b serves to provide the third electrode layer 120 to have a more appropriate work function relative to the second active layer 122. The material of the work function adjustment layer 110b includes, for example, PEDOT:PPS, molybdenum oxide, or other work function adjustment materials.

The second active layer 122 covers the third electrode layer 120. The second active layer 122 absorbs the light of the second wavelength range. According to an exemplary embodiment, the second active layer 122 is, for example, an organic light absorption material and mainly absorbs the light of the infrared light band and the light of the visible light band. If the second active layer 122 absorbs the light of the visible light band, the material of the second active layer 122 includes, for example, (poly(3-hexylthiophene):[6,6]-phenyl-C61-butyric acid methyl ester (P3HT:[60]PCBM)), (poly[2-methoxy-5-(30,70-dimethyloctyloxy)-1,4-phenylenevinylene]:[6,6]-phenyl-C61-butyricacidmethyl ester (MDMO-PPV:[60]PCBM)), or other appropriate materials. If the first active layer 112 absorbs light of the infrared red light band, the material of the first active layer 112 may include, for example, (poly[2,6-(4,4-bis-(2-ethylhexyl)-4H-cyclopenta [2,1-b;3 ,4-b′]dithiophene)-alt-4,7-(2,1,3 -benzothiadiazole)]:[6,6]-phenyl-C71 butyric acid methyl ester (PCPDTBT: [70]PCBM)), (poly[4,8-bis-substituted-benzo[1,2-b:4,5-b′]dithiophene-2,6-diyl-alt-4-substituted-thieno [3,4-b]thio-phene-2,6-diyl]:[6,6]-phenyl-C71 butyric acid methyl ester (PBDTTT:[70]PCBM)), or other appropriate materials.

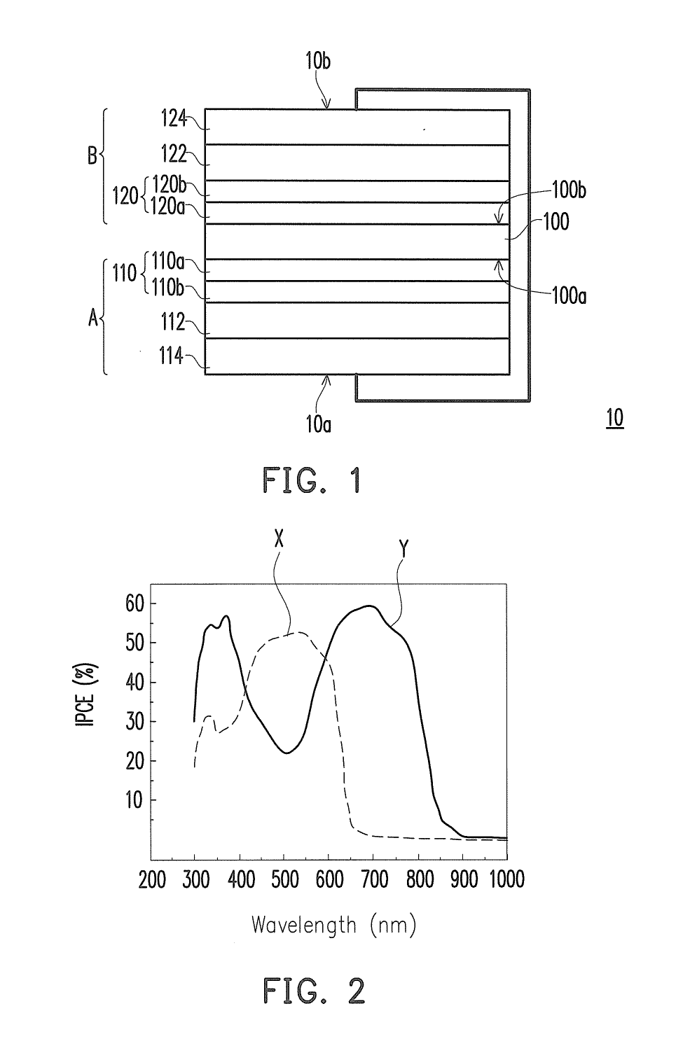

It is worthy to note that, the second active layer 122 of the second photovoltaic cell B and the first active layer 112 of the first photovoltaic cell A absorb light of different wavelength ranges. As shown in FIG. 2, the y-axis represents the incident photon conversion efficiency (IPCE (%)), while the x-axis represents the wavelength. If the first active layer 112 of the photovoltaic cell A absorbs the light of the visible light band (such as curve X), the second active layer 122 of the second photovoltaic cell B absorbs light of the infrared light band (such as curve Y). In contrast, if the first active layer 112 of the first photovoltaic cell A absorbs the light of the infrared light band (such as curve Y), the second active layer 122 of the second photovoltaic cell B absorbs the light of the visible light band (such as curve X).

Moreover, the fourth electrode layer 124 covers the second active layer 122. According to an exemplary embodiment, the forth electrode layer 124 includes, for example, a metal electrode material. In another exemplary embodiment, the fourth electrode layer 124 includes high conductivity and high reflective metal material, such as aluminum, silver, or other alloys.

In the above photovoltaic cell module 10, the surface of the second electrode layer 114 of the first photovoltaic cell A may serve as the light incident surface 10a of the photovoltaic cell module 10, while the surface of the fourth electrode layer 124 of the second photovoltaic cell B may serve as a light reflective surface 10b of the photovoltaic cell module 10. After an external light is incident into the photovoltaic cell module 10 through the light incident surface 10a and passes through the photovoltaic cell A, the light of the first wavelength range is absorbed by the first active layer 112. After further transmitting through the substrate 100, the light of the second wavelength range is absorbed by the second active layer 122 as the light passes through the second photovoltaic cell B. Ultimately, the light is reflected by the fourth electrode layer 124 and again passes through the second active layer 122 (absorbing the second wavelength range) and the first active layer 112 (absorbing the first wavelength range). Accordingly, the light absorption efficiency of the photovoltaic cell module 10 is effectively enhanced.

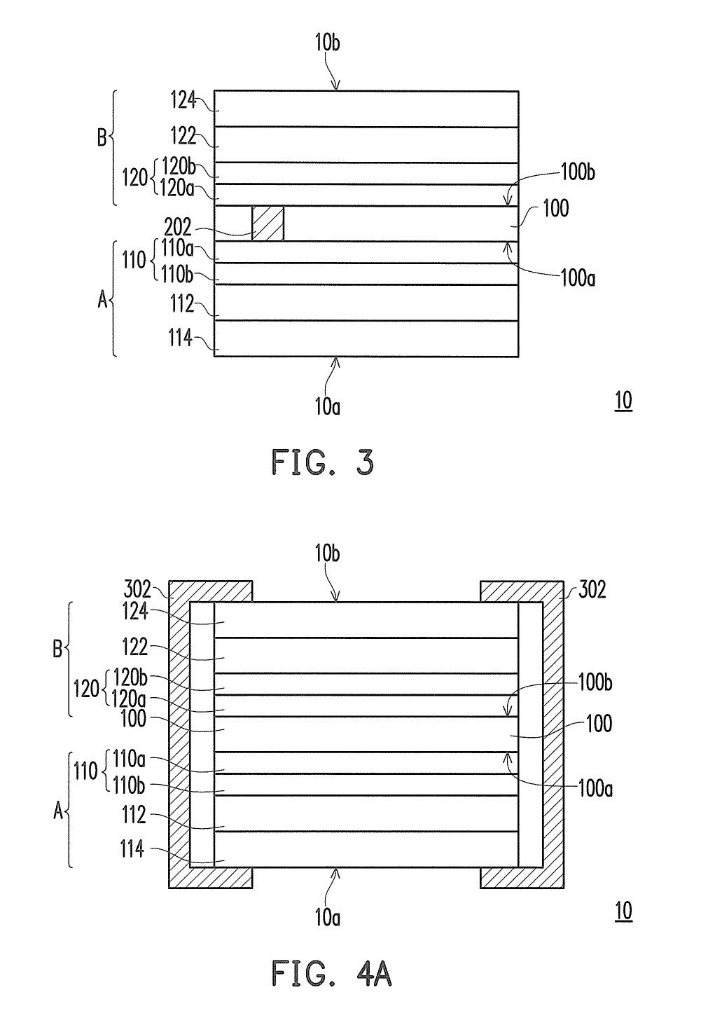

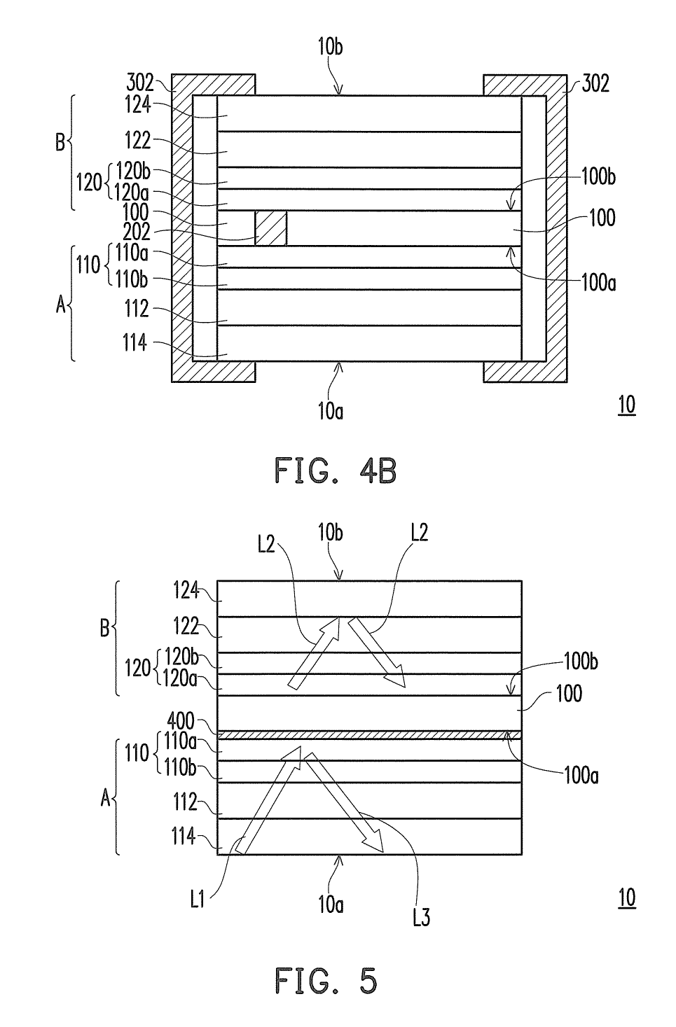

In this exemplary embodiment, the first photovoltaic cell A and the second photovoltaic cell B of the photovoltaic cell module 10 are serially connected together. To serially connect the first photovoltaic cell A and the second photovoltaic cell B together is accomplished by a method as shown in FIG. 3 or a method as shown in FIGS. 4A to 4B. Referring to FIG. 3, an interconnecting structure 202 is disposed in the substrate 100 of the photovoltaic cell module 10. More specifically, one end of the interconnecting structure 202 is electrically connected to the first electrode layer 110 of the first photovoltaic cell A, while another end of the interconnecting structure 202 is electrically connected to the third electrode layer 120 of the second photovoltaic cell B. Hence, the first photovoltaic cell A and the second photovoltaic cell B are electrically connected to each other in serious. Forming the interconnecting structure 202 in the substrate 100 includes forming a through hole in the substrate 100, followed by filling the through hole with a conductive polymer material or a metal adhesive (for example, silver adhesive).

According to other exemplary embodiments, the interconnecting structure 202 may also be formed in the substrate 100 and the second photovoltaic cell B to electrically connect the first electrode 110 of the first photovoltaic cell A and the fourth electrode 124 of the second photovoltaic cell B. Alternatively, the interconnecting structure 202 may be formed in the substrate 100, and in the first photovoltaic cell A and the second photovoltaic cell B to electrically connect the second electrode 114 of the first photovoltaic cell A and the fourth electrode 124 of the second photovoltaic cell B.

According to the exemplary embodiment in FIG. 4A, an external circuit board 302 is disposed at the exterior of the photovoltaic cell module 10 to serially connect the first photovoltaic cell A and the second photovoltaic cell B together. More specifically, one end of the external circuit board 302 is electrically connected to the second electrode layer 114 of the first photovoltaic cell A, while another end is electrically connected to the fourth electrode layer 124 of the second photovoltaic cell B. Although in the exemplary embodiment as shown in FIG. 4A, two external circuit boards are applied to serially connect the first photovoltaic cell A and the second photovoltaic cell B, the application of two external circuit boards should not be construed as limited to the embodiments set forth herein. According to another exemplary embodiment, one external circuit board is disposed for serially connecting the first photovoltaic cell A and the second photovoltaic cell B.

Similarly, according to other exemplary embodiments, the external circuit board 302 electrically connects the first electrode 110 of the first photovoltaic cell A with the fourth electrode 124 of the second photovoltaic cell B. Alternatively, the external circuit board 302 electrically connects the second electrode 114 of the first photovoltaic cell A with the third electrode 120 of the second photovoltaic cell B. In yet another exemplary embodiment, the external circuit board 302 electrically connects the first electrode 110 of the first photovoltaic cell A with the third electrode 120 of the second photovoltaic cell B.

In the photovoltaic cell module 10 of the exemplary embodiment illustrated in FIG. 4B, aside from disposing an interconnecting structure 202 in the substrate 100, a circuit board 302 is also disposed at the exterior of the photovoltaic cell module 10 to serially connect the first photovoltaic cell A with the second photovoltaic cell B. As shown in FIG. 4B, the first end of the interconnecting structure 202 is electrically connected to the first electrode layer 110 of the first photovoltaic cell A, while another end of the interconnecting structure 202 is electrically connected to the third electrode layer 120 of the second photovoltaic cell B to serially connect the first photovoltaic cell A and the second photovoltaic cell B together. In another exemplary embodiment, the interconnecting structure 202 is formed in the substrate 100 and the second photovoltaic cell B to electrically connect the first electrode 110 of the first photovoltaic cell A with the fourth electrode 124 of the second photovoltaic cell B. Alternatively, the interconnecting structure 202 is formed in the substrate 100 and the first photovoltaic cell A to electrically connect the second electrode 114 of the first photovoltaic cell A with the third electrode 120 of the second photovoltaic cell B. In another exemplary embodiment, the interconnecting structure 202 is formed in the substrate 100, and the first photovoltaic cell A and the second photovoltaic cell B to electrically connect the second electrode 114 of the first photovoltaic cell A with the fourth electrode 124 of the second photovoltaic cell B.

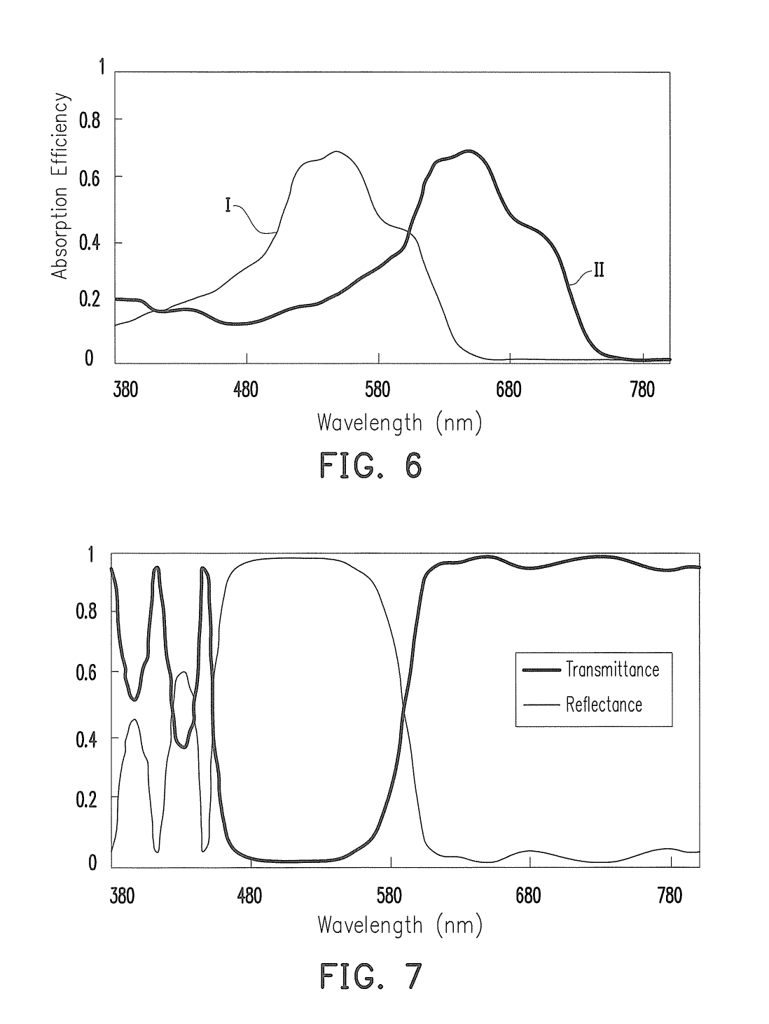

FIG. 5 is a schematic cross-sectional view of a photovoltaic cell module according to one exemplary embodiment of the disclosure. The exemplary embodiment of FIG. 5 is similar to that of FIG. 1; hence, wherever possible, the same or similar reference numbers are used to refer to the same or like parts. Distinguished from the photovoltaic cell module of FIG. 1, the photovoltaic cell module of FIG. 5 further includes an optical film 400, and the optical film 400 is disposed on the first surface 100a or the second surface 100b of the substrate 100. The optical film 400 has the characteristics that the light of the first wavelength range (the wave band absorbed by the first active layer 112) is reflected, while the light of the second wavelength range (the wave band absorbed by the second active layer 122) is transmitted through. According to an exemplary embodiment, the first active layer 112 of the first photovoltaic cell A absorbs the light of the visible light band (such as, curve I of FIG. 6), while the second active layer 122 of the second photovoltaic cell B absorbs the light of the infrared light band (such as, curve II in FIG. 6). An optical film 400 may be designed to comprise the characteristics of light reflection of the visible light band and light transmission of the infrared light band.

More specifically speaking, as shown in FIG. 7, the optical film 400 of this exemplary embodiment reflects the light of the visible light wave band (such as, the reflectance curve) and allows the transmission of the light of the wave bands other than the visible light wave band (such as, transmittance curve). In this exemplary embodiment, the optical film 400 reflects the light of the visible light wave band with a wavelength of 450 to 600 nm, and allows an ultraviolet light with a wavelength below 450 nm and an infrared light with a wavelength above 600 nm to transmit through.

Accordingly, as shown in FIG. 5, when the external light L1 is incident into the photovoltaic cell 10 through the light incident surface 10a and transmits through the first photovoltaic cell A, the light of the visible light wave band is absorbed by the first active layer 112. As the light L1 continues to transmit to the optical film 400, the light L3 of the visible light wave band is reflected by the optical film, while the light L2 of the infrared light wave band transmits through the optical film 400. More particularly, the reflected light of the visible light wave band L3 transmits through the first active layer 112 again and is absorbed one more time before transmitting through the photovoltaic cell module 10. Moreover, after the light L2 of the infrared light wave band transmits through the optical film 400, it is absorbed by the second active layer 122 when it transmits through the second photovoltaic cell B. Then, the light L2 of the infrared light wave band is reflected by the fourth electrode layer 124 and further passes through the second active layer 122 again and is absorbed one more time.

Alternatively speaking, by disposing an optical film in the photovoltaic cell module 10 of the exemplary embodiment, a majority of the light of the first wavelength range (for example, the visible light) is prevented from passing through the optical film 400. Hence, a majority of the light the first wavelength range (for example, the visible light) is absorbed by the first active layer 112. More specifically, since a majority of the light the first wavelength range (for example, the visible light) does not transmit through the optical film 400, the majority of the light of the first wavelength range (for example, the visible light) is restrained from being absorbed or consumed by the film layer of the second photovoltaic cell B. Accordingly, the light of the first wavelength range (for example, the visible light) can be completely absorbed by the first active layer 112. Thus, the disposition of the optical film 400 in the photovoltaic cell module 10 may further enhance the light absorption efficiency of the first photovoltaic cell A to enhance the overall efficiency of the photovoltaic cell module 10.

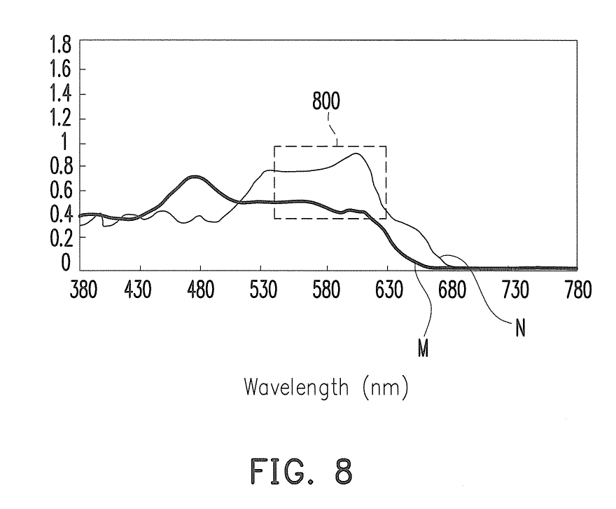

FIG. 8 is a curve diagram of the light absorption efficiency and the wavelength of the photovoltaic cell module in FIG. 5. Referring to FIG. 8, the curve M represents the absorption curve of the photovoltaic cell module in the absence of an optical film disposed therein, and the curve N represents the absorption curve of the photovoltaic cell module having an optical film disposed therein. Referring to FIG. 8, the optical absorption efficiency in the visible light region (region 800) is higher for curve N than for curve M, and the optical absorption efficiency is increased by about 22%. Accordingly, configuring an optical film in a photovoltaic cell module may further enhance the light absorption efficiency of the first photovoltaic cell and to further enhance the overall efficiency of the photovoltaic cell module.

According to the exemplary embodiments of the disclosure, a first photovoltaic cell and a second photovoltaic cell are disposed at two sides of the substrate to obviate the film layers of the two photovoltaic cells from damaging each other during the fabrication process. Moreover, the first photovoltaic cell of the exemplary embodiments of the invention absorbs the light of the first wavelength range and the second photovoltaic cell of the exemplary embodiments absorbs the light of the second wavelength range. With this type of design of a photovoltaic cell module, the light absorption efficiency of the entire wavelength length range of the photovoltaic cell module is efficiently enhanced to raise the overall efficiency of the photovoltaic cell module.

According to an exemplary of the invention, an optical film may be disposed in a photovoltaic cell module, such that the light of the first wavelength range is reflected, while the light of the second wavelength range is transmitted through. In consequence, the light absorption efficiency of the first photovoltaic cell in the photovoltaic cell module is enhanced to raise the efficiency of the photovoltaic cell module.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic cell module, comprising a light incident surface and a light reflective surface, the photovoltaic cell module comprising:
a substrate, comprising a first surface and a second surface;
a first photovoltaic cell, comprising:
a first electrode layer, disposed on the first surface of the substrate;
a first active layer, covering the first electrode layer, wherein the first active layer absorbs a light of a first wavelength range;
a second electrode layer, covering the first active layer;
a second photovoltaic cell, serially connected with the first photovoltaic cell, the second photovoltaic cell comprising:
a third electrode layer, disposed on the second surface of the substrate;
a second active layer, covering the third electrode layer, wherein the second active layer absorbs a light of a second wavelength range;
a fourth electrode layer, covering the second active layer,
wherein a surface of the second electrode layer of the first photovoltaic cell serves as the light incident surface and a surface of the fourth electrode layer of the second photovoltaic cell of the second photovoltaic cell serves as the light reflective surface.

2. The photovoltaic cell module of claim 1, wherein the first active layer and the second active layer are respectively an organic light absorption material.

3. The photovoltaic cell module of claim 1, wherein one of the first active layer and the second active layer absorbs a visible light, while another of the first active layer and the second active layer absorbs an infrared light.

4. The photovoltaic cell module of claim 1, further comprising an optical film, disposed on the substrate, the light of the first wavelength range is reflected by the optical film, and the light of the second wavelength range is transmitted by the optical film.

5. The photovoltaic cell module of claim 4, wherein the optical film comprises at least a layer of a first reflective index dielectric layer and at least a layer of a second reflective index dielectric layer alternately stacked, wherein a reflective index of the first reflective index dielectric layer is different from a reflective index of the second reflective index dielectric layer.

6. The photovoltaic cell module of claim 1, further comprising an interconnecting structure disposed in the substrate to electrically connect the first photovoltaic cell and the second photovoltaic cell.

7. The photovoltaic cell module of claim 1, further comprising an external circuit board for electrically connecting the first photovoltaic cell and the second photovoltaic cell.

8. The photovoltaic cell module of claim 1, wherein the first electrode layer, the second electrode layer, and the third electrode layer comprise a transparent electrode material respectively, and the fourth electrode layer comprises a metal electrode material.

9. The photovoltaic cell module of claim 8, wherein the first electrode layer comprises a transparent conductive layer and a work function adjustment layer.

10. The photovoltaic cell module of claim 8, wherein the second electrode layer comprises an organic conductive material.

11. The photovoltaic cell module of claim 8, wherein the third electrode layer comprises a transparent conductive layer and a work function adjustment layer.

12. The photovoltaic cell module of claim 8, wherein the substrate is a flexible substrate.
